(19) United States
(12) Patent Application Publication
(10) Pub. No.: US 2004/0137680 A1
(43) Pub. Date: Jul. 15, 2004

(54) Manufacturing method of semiconductor device

(75) Inventor: Akira Matsumura, Hyogo (JP)

Correspondence Address: McDermott Will & Emery, 600 13th Street, N.W., Washington, DC, 20005-3096, US

(73) Assignee: RENESAS TECHNOLOGY CORP.

(21) Appl. No.: 10/614,022

(22) Filed: Jul. 8, 2003

(30) Foreign Application Priority Data
Jan. 15, 2003 (JP) 2003-007408(P)

(51) Int. Cl. H01L 21/8242

(52) U.S. Cl. 438/255; 438/398

(57) ABSTRACT

A silicon nitride film, having a greater selective ratio with respect to an interlayer insulating film than a resist film under a prescribed etching condition and harder to polish upon chemical mechanical polishing than the interlayer insulating film, is formed on the interlayer insulating film. This silicon nitride film is used as a hard mask to prevent reduction in height of the interlayer insulating film during chemical mechanical polishing for forming a capacitor lower electrode. The silicon nitride film is also used as an etching mask during etching for forming a hole.

### BACKGROUND OF THE INVENTION

1. Field of the Invention

The present invention relates to a manufacturing method of a semiconductor device provided with a capacitor.

2. Description of the Background Art

Conventionally, a semiconductor device provided with a capacitor above a semiconductor substrate extending in a vertical direction with respect to a main surface of the semiconductor substrate has been manufactured. In the semiconductor device provided with such a capacitor, it is desired to lessen the area in a direction parallel to the main surface of the semiconductor substrate and to increase the capacitance. To this end, the capacitor should be increased in height in a vertical direction with respect to the main surface of the semiconductor substrate, which leads to an increased aspect ratio of the capacitor.

In the capacitor having such a high aspect ratio, a hole in which the capacitor is to be formed is formed by etching an insulating film. Since there is a limit to control the aspect ratio of the hole with such etching, it is difficult to form a capacitor in a desired shape, particularly a storage electrode in a desired shape, in the hole, hindering improvement of properties of the capacitor.

In addition, in forming a lower electrode of the capacitor described above, an upper surface of the insulating film constituting the hole for forming the capacitor therein is polished by CMP (Chemical Mechanical Polishing). During the CMP process, the upper surface of the insulating film on which the capacitor lower electrode is to be formed is over-polished. This makes it difficult to increase the height of the capacitor in a vertical direction with respect to the main surface of the semiconductor substrate, again hindering improvement of the properties of the capacitor.

### SUMMARY OF THE INVENTION

An object of the present invention is to provide a manufacturing method of a semiconductor device having a capacitor improved in properties.

A manufacturing method of a semiconductor device according to a first aspect of the present invention includes the steps of: forming an insulating film above a semiconductor substrate; forming, on the insulating film, a hard mask that is harder to polish than the insulating film upon chemical mechanical polishing and has a greater selective ratio with respect to the insulating film than a resist film under a prescribed etching condition; and forming a hole penetrating the hard mask and the insulating film to extend in a vertical direction with respect to a main surface of the semiconductor substrate. The manufacturing method further includes the steps of: forming a capacitor lower electrode along a side surface of the hole; forming a capacitor dielectric film along a surface of the capacitor lower electrode; and forming a capacitor upper electrode to contact a surface of the capacitor dielectric film.

According to the manufacturing method described above, chemical mechanical polishing for forming the capacitor lower electrode can be carried out using the hard mask harder to polish than the insulating film upon chemical mechanical polishing as the CMP stopper film. This can prevent the insulating film from being polished excessively during the chemical mechanical polishing, and thus, prevent the hole from being decreased in height from a desired height. As a result, the capacitor lower electrode of a desired height can be formed in the hole, and thus, the capacitance can be increased.

Further, according to the manufacturing method described above, etching for forming the hole can be carried out using the hard mask having a greater selective ratio with respect to the insulating film than a resist film under a prescribed etching condition as the etching mask. This suppresses formation of a hole in a taper shape widening toward its upper side. As a result, a capacitor in a good shape can be formed even when the capacitor is more downsized. Accordingly, the properties of the downsized capacitor can be improved.

A manufacturing method of a semiconductor device according to a second aspect of the present invention includes the steps of: forming a first insulating film above a semiconductor substrate; and forming, on the first insulating film, a second insulating film different in composition from the first insulating film. The manufacturing method further includes the steps of: forming, on the second insulating film, a hard mask same in composition with the first insulating film and harder to polish than the second insulating film upon chemical mechanical polishing; and forming, on the hard mask, an etching stopper film having a greater selective ratio than the hard mask under a prescribed etching condition. The manufacturing method further includes the step of forming a hole penetrating the etching stopper film, the hard mask, the second insulating film and the first insulating film to extend in a vertical direction with respect to a main surface of the semiconductor substrate, by etching with the etching stopper film used as a mask. The manufacturing method further includes the steps of: forming a film to be a capacitor lower electrode on a side surface of the hole and an upper surface of the hard mask; and forming a buried film to bury the film to be the capacitor lower electrode. The method further includes the step of forming the capacitor lower electrode by removing the buried film, the film to be the capacitor lower electrode and the etching stopper film by chemical mechanical polishing to expose the hard mask. The method further includes the steps of: forming a capacitor dielectric film at a surface of the capacitor lower electrode; and forming a capacitor upper electrode at a surface of the capacitor dielectric film.

According to the manufacturing method described above, chemical mechanical polishing for forming the capacitor lower electrode can be carried out using the hard mask harder to polish than the insulating film upon chemical mechanical polishing as the CMP stopper film. This prevents the insulating film from being polished excessively during the chemical mechanical polishing, and thus, the hole can be prevented from being lowered than its desired height. As a result, the capacitor lower electrode of a desired height can be formed in the hole, and accordingly, the capacitor capacitance can be increased.

In addition, etching of the first insulating film is carried out with the etching stopper film formed on the hard mask. This suppresses thinning of the upper surface of the hard mask upon etching of the first insulating film, and thus, flatness of the upper surface of the hard mask can be improved. As a result, a layer to be stacked on the hard mask can be formed in a good shape, and accordingly, the yield of the semiconductor devices can be improved.

A manufacturing method of a semiconductor device according to a third aspect of the present invention includes the steps of: forming a first insulating film above a semiconductor substrate; and forming, on the first insulating film, a second insulating film different in composition from the first insulating film. The manufacturing method further includes the steps of: forming, on the second insulating film, a hard mask same in composition with the first insulating film and having a greater selective ratio with respect to the second insulating film than a resist film under a first prescribed etching condition; and forming, on the hard mask, an etching stopper film having a greater selective ratio than the hard mask under a second prescribed etching condition. The manufacturing method further includes the step of forming a hole penetrating the etching stopper film, the hard mask, the second insulating film and the first insulating film to extend in a vertical direction with respect to a main surface of the semiconductor substrate, by etching with the etching stopper film used as a mask. The manufacturing method further includes the steps of: forming a film to be a capacitor lower electrode on a side surface of the hole and an upper surface of the hard mask; and forming a buried film to bury the film to be the capacitor lower electrode. The manufacturing method further includes the step of forming the capacitor lower electrode by removing the buried film, the film to be the capacitor lower electrode and the etching stopper film by chemical mechanical polishing to expose the hard mask. The manufacturing method further includes the steps of: forming a capacitor dielectric film on a surface of the capacitor lower electrode; and forming a capacitor upper electrode on a surface of the capacitor dielectric film.

According to the manufacturing method described above, etching for forming the hole can be carried out using the hard mask having a greater selective ratio with respect to the insulating film than a resist film under the first prescribed etching condition as the etching mask. This suppresses formation of a hole in a taper shape widening toward the upper side. As a result, the capacitor can be formed in a good shape even if it is downsized. Accordingly, properties of the downsized capacitor can be improved.

In addition, etching of the first insulating film is carried out under the second prescribed condition, with the etching stopper film formed on the hard mask. This suppresses thinning of the upper surface of the hard mask upon etching of the first insulating film, and thus, flatness of the upper surface of the hard mask can be improved. As a result, a layer to be stacked on the hard mask can be formed in a good shape, so that the yield of the semiconductor devices can be improved.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a structure of each of semiconductor devices according to first and second embodiments of the present invention.

FIGS. 2-9 illustrate a manufacturing method of the semiconductor device of the first embodiment.

FIGS. 10-17 illustrate a manufacturing method of the semiconductor device of the second embodiment.

FIGS. 18 and 19 illustrate a manufacturing method of a semiconductor device according to a third embodiment of the present invention.

### DESCRIPTION OF THE PREFERRED EMBODIMENTS

Hereinafter, semiconductor devices and manufacturing methods thereof according to embodiments of the present invention will be described with reference to the drawings.

First Embodiment

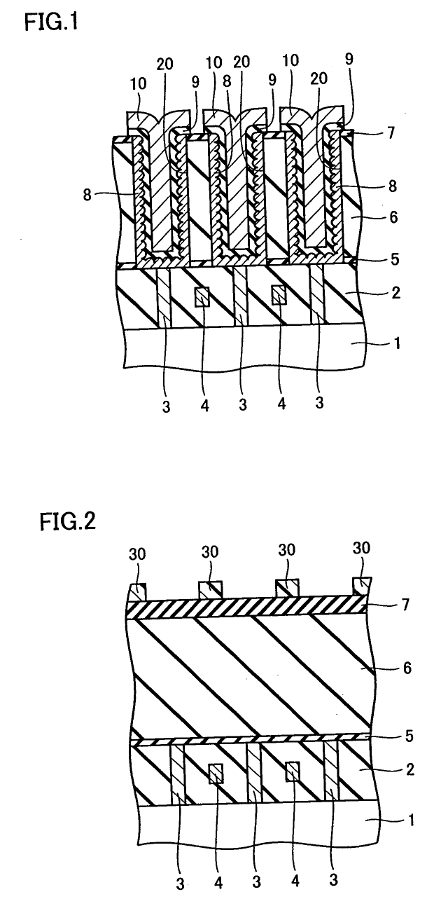

Firstly, a structure of the semiconductor device of the first embodiment is described with reference to FIG. 1.

Referring to FIG. 1, the semiconductor device of the present embodiment has a structure as follows. An interlayer insulating film 2 is formed on a semiconductor substrate 1. A contact plug 3 is formed to penetrate interlayer insulating film 2 in a vertical direction to connect to semiconductor substrate 1. A bit line 4 is provided between neighboring contact plugs 3. A silicon nitride film 5 is formed on interlayer insulating film 2 to serve as an etching stopper film.

An interlayer insulating film 6 of BPTEOS (Boro-Phospho Tetra Ethyl Ortho Silicate) is formed on silicon nitride film 5. On interlayer insulating film 6, a silicon nitride film 7 is formed which serves as a hard mask having a greater selective ratio with respect to interlayer insulating film 6 than a resist film under a prescribed etching condition and harder to polish by CMP than interlayer insulating film 6. Further, a hole 20 is formed to penetrate silicon nitride film 7, interlayer insulating film 6 and silicon nitride film 5, and to have its bottom surface partly consisting of contact plug 3.

A capacitor lower electrode 8 is formed along the surface of hole 20. A capacitor dielectric film 9 is formed along the surface of capacitor lower electrode 8. A capacitor upper electrode 10 is formed to fill in a concave portion formed by capacitor dielectric film 9.

According to the above-described structure of the semiconductor device of the present embodiment, capacitor lower electrode 8 is formed to contact side surfaces of silicon nitride film 7 and interlayer insulating film 6. This can increase the capacitance compared to the case of a capacitor having capacitor lower electrode 8 not formed to contact the side surfaces of silicon nitride film 7 and interlayer insulating film 6.

Next, a manufacturing method of the semiconductor device of the present embodiment is described with reference to FIGS. 2-9.

Firstly, the structure shown in FIG. 2 is explained. In the structure shown in FIG. 2, semiconductor substrate 1, interlayer insulating film 2, contact plug 3 and bit line 4 are as described above in conjunction with FIG. 1. At the stage where contact plug 3 has been formed, silicon nitride film 5 is formed to cover the surfaces of interlayer insulating film 2 and contact plug 3.

Thereafter, interlayer insulating film 6 of BPTEOS is formed on silicon nitride film 5. Next, silicon nitride film 7 is formed on interlayer insulating film 6. Silicon nitride film 7 serves as a hard mask which has a greater selective ratio with respect to interlayer insulating film 6 than a resist film under a prescribed etching condition and is harder to polish by CMP than interlayer insulating film 6. Silicon nitride film 5 serves as an etching stopper.

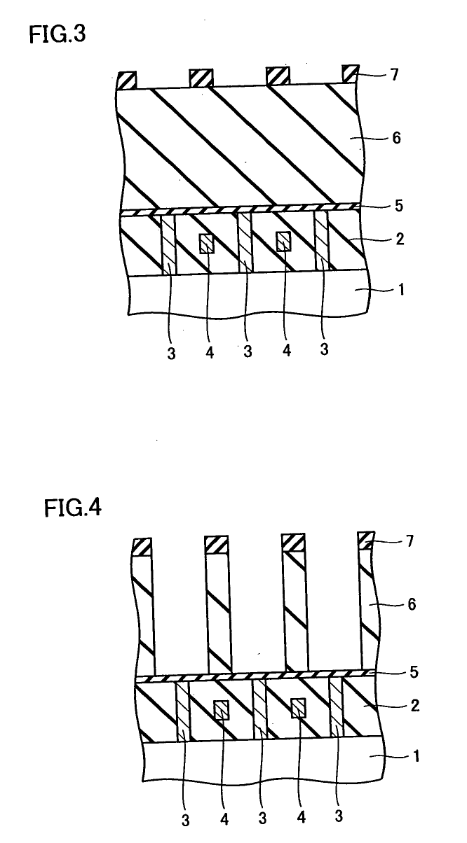

Thereafter, on silicon nitride film 7, a resist film 30 is patterned into a prescribed pattern. The structure shown in FIG. 2 is thus obtained. Next, silicon nitride film 7 is etched, using resist film 30 as a mask, to expose a surface of interlayer insulating film 6. Thereafter, resist film 30 is removed. As such, the structure shown in FIG. 3 is obtained.

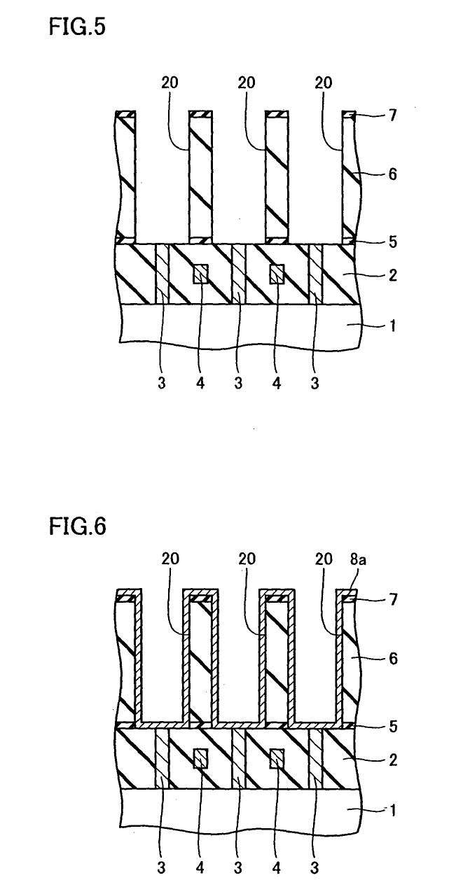

Next, interlayer insulating film 6 is etched, using above-described silicon nitride film 7 having a greater selective ratio with respect to interlayer insulating film 6 than the resist film under a prescribed etching condition as a mask, to expose a surface of silicon nitride film 5. The structure shown in FIG. 4 is thus obtained. Next, silicon nitride film 5 is etched, using interlayer insulating film 6 as a mask. As such, hole 20 is formed with side surfaces of silicon nitride films 5, 7, side surface of interlayer insulating film 6, and upper surfaces of interlayer insulating film 2 and contact plug 3. The structure shown in FIG. 5 is thus obtained.

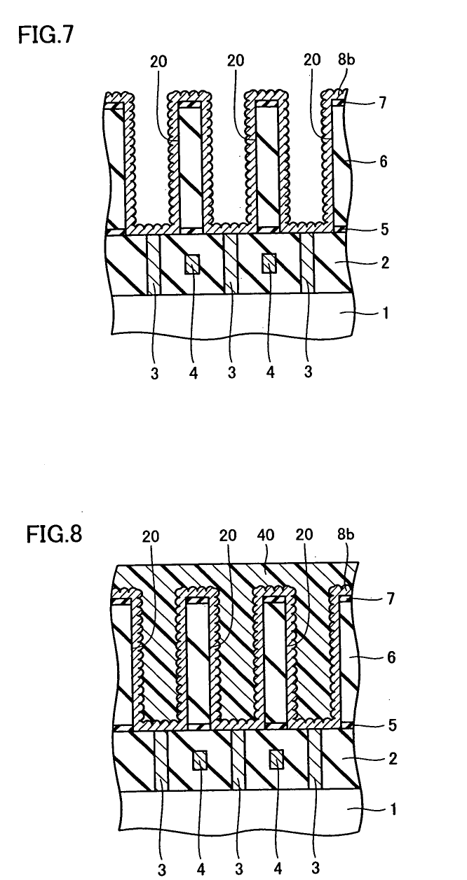

Next, as shown in FIG. 6, a film 8a to be a capacitor lower electrode is formed to cover the surface of hole 20 and the upper surface of silicon nitride film 7. Thereafter, as shown in FIG. 7, the surface of film 8a to be the capacitor lower electrode is roughened. Thus, a film 8b to be the capacitor lower electrode is formed, of which structure is shown in FIG. 7.

Next, as shown in FIG. 8, a buried film 40 of, e.g., photoresist or silicon oxide film, is formed to bury the film 8b to be the capacitor lower electrode.

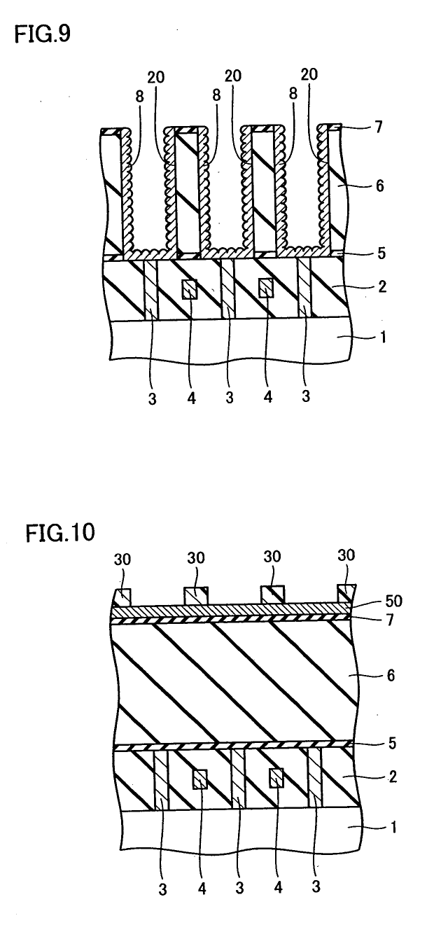

Next, buried film 40 is gradually polished from its upper surface by CMP. Thus, the surface of silicon nitride film 7 is exposed, as shown in FIG. 9, so that capacitor lower electrode 8 is formed.

Next, a capacitor dielectric film 9 is formed along the surface of capacitor lower electrode 8. Thereafter, a capacitor upper electrode 10 is formed to fill in a concave portion formed by the surface of capacitor dielectric film 9. As a result, the structure shown in FIG. 1 is obtained.

According to the manufacturing method of the semiconductor device of the present embodiment, in the step of forming hole 20 where the capacitor is to be formed, interlayer insulating film 6 is etched in the state where silicon nitride film 7 having a greater selective ratio with respect to interlayer insulating film 6 than the resist film under a prescribed etching condition is formed on interlayer insulating film 6, as shown in FIG. 4.

According to this manufacturing method, the selective ratio of silicon nitride film 7 with respect to interlayer insulating film 6 is greater than in a conventional manufacturing method where interlayer insulating film 6 is etched to form hole 20 using a resist film as a mask. This permits formation of hole 20 in a more favorable shape. As a result, the surface area of the capacitor can be increased, and accordingly, the capacitance can be improved.

Furthermore, the above-described silicon nitride film 7 as the hard mask is not removed in a subsequent step, but utilized as a CMP stopper film in the CMP step. This prevents over-polishing of the upper surface of interlayer insulating film 6 in the CMP step. Thus, it is possible to increase the height of hole 20 where the capacitor is to be formed, and thus to increase the capacitance. Since polysilicon is prevented from being left between neighboring storage electrodes, short circuit between the capacitors is prevented. This results in an improved yield of the semiconductor devices.

Second Embodiment

A structure of the semiconductor device of the second embodiment and manufacturing method thereof are described with reference to FIGS. 1 and 10-17.

Firstly, the structure of the semiconductor device of the second embodiment is explained with reference to FIG. 1. As shown in FIG. 1, the structure of the semiconductor device of the present embodiment is completely identical to that of the semiconductor device of the first embodiment.

Thus, the semiconductor device of the present embodiment can enjoy the same effects as in the semiconductor device of the first embodiment.

Now, the manufacturing method of the semiconductor device of the present embodiment is explained with reference to FIGS. 10-17. Firstly, the structure shown in FIG. 10 is explained. The structure of the semiconductor device shown in FIG. 10 is almost identical to the structure of the semiconductor device of the first embodiment explained in conjunction with FIG. 2. The structure of the present embodiment shown in FIG. 10 differs from that of the first embodiment in FIG. 2 only in that a polycrystalline silicon film 50 as an etching stopper film is formed on silicon nitride film 7 and a resist film 30 is formed on polycrystalline silicon film 50.

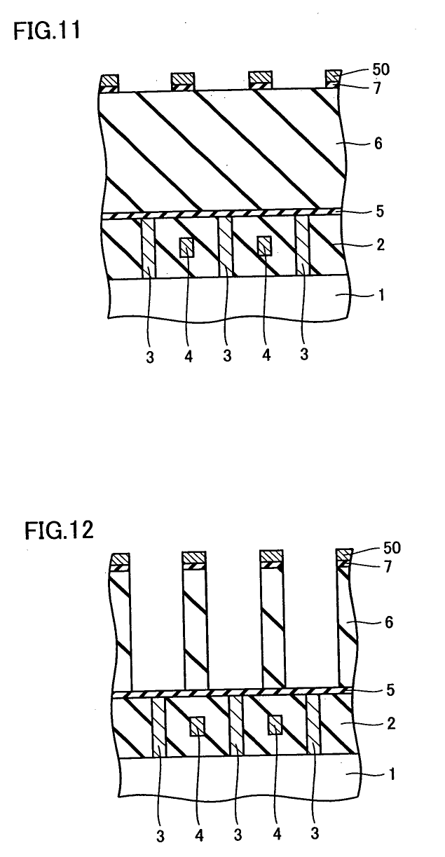

After formation of the structure shown in FIG. 10, polycrystalline silicon film 50 and silicon nitride film 7 are etched, using resist film 30 as a mask, to expose the upper surface of interlayer insulating film 6, as shown in FIG. 11.

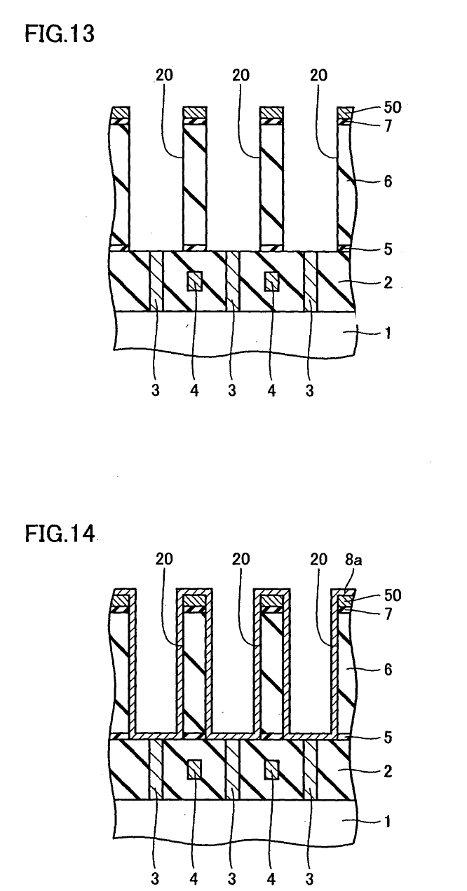

Next, interlayer insulating film 6 is etched, using polycrystalline silicon film 50 as an etching mask, to expose the upper surface of silicon nitride film 5, as shown in FIG. 12. Next, silicon nitride film 5 is removed, using polycrystalline silicon film 50 as an etching mask. As such, hole 20 is formed as shown in FIG. 13.

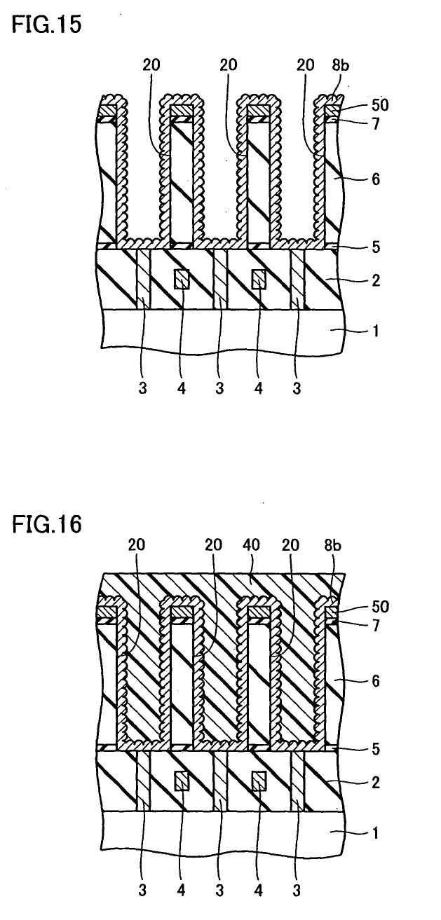

Thereafter, as shown in FIG. 14, a film 8a to be a capacitor lower electrode is formed on the surface of hole 20, i.e., continuously on upper surfaces of interlayer insulating film 2 and contact plug 3, and side surfaces of silicon nitride film 5, interlayer insulating film 6, silicon nitride film 7 and polycrystalline silicon film 50. Thereafter, the surface of film 8a to be the capacitor lower electrode is roughened to form a film 8b to be the capacitor lower electrode as shown in FIG. 15.

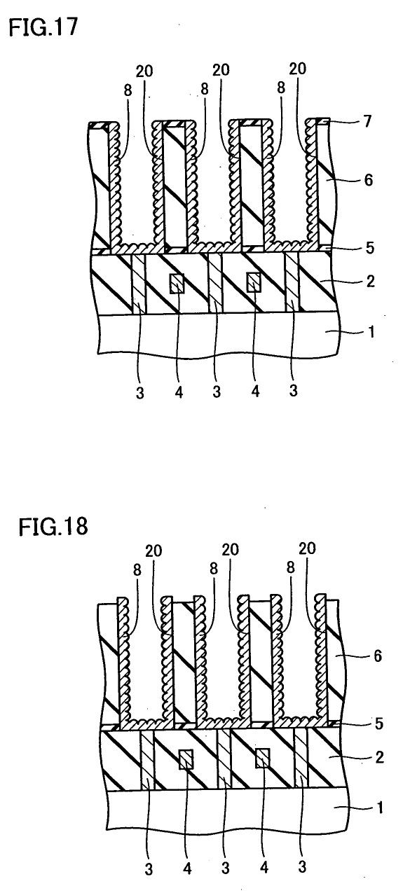

Next, as shown in FIG. 16, a buried film 40 of resist film or silicon oxide film is filled in a concave portion formed by film 8b to be the capacitor lower electrode.

Thereafter, as shown in FIG. 17, buried film 40, film 8b to be the capacitor lower electrode, and polycrystalline silicon film 50 are removed by CMP, to expose the upper surface of silicon nitride film 7. As such, capacitor lower electrode 8 is formed, as shown in FIG. 17. Thereafter, a capacitor dielectric film 9 is formed along the surface of capacitor lower electrode 8. Next, a capacitor upper electrode 10 is formed to fill in a concave portion formed by the surface of capacitor dielectric film 9. Accordingly, the semiconductor device of the structure as shown in FIG. 1 is obtained.

The above-described manufacturing method of the semiconductor device of the present embodiment exhibits the following effects.

In the manufacturing method of the semiconductor device of the first embodiment, silicon nitride film 7 is used as an etching stopper film upon etching of silicon nitride film 5, as shown in FIG. 4. By comparison, in the manufacturing method of the semiconductor device of the present embodiment, polycrystalline silicon film 50, formed on silicon nitride film 7, is used as an etching stopper film upon etching of silicon nitride film 5, as shown in FIG. 12.

In the manufacturing method of the semiconductor device of the first embodiment, thinning of silicon nitride film 7 occurs upon etching of silicon nitride film 5. Thus, it is necessary to prepare silicon nitride film 7 as the hard mask somewhat thicker than silicon nitride film 5 as the bottom stopper film, taking account of such thinning. In addition, the thickness of silicon nitride film 7 to be used as the CMP stopper film cannot be stabilized due to variation in the degree of thinning.

By comparison, in the manufacturing method of the semiconductor device of the present embodiment, the hard mask is formed as a two-layer structure of polycrystalline silicon film 50 and silicon nitride film 7, so that thinning of silicon nitride film 7 during etching of silicon nitride film 5 is prevented. As a result, silicon nitride film 7 is stabilized in thickness. In addition, polycrystalline silicon film 50 is always removed when film 8b to be the capacitor lower electrode is removed by CMP. As a result, silicon nitride film 7 of a stable thickness can be used as the CMP stopper film.

As described above, according to the manufacturing method of the semiconductor device of the present embodiment, a capacitor having more stable capacitance than the one obtained by the manufacturing method of the semiconductor device of the first embodiment can be manufactured. Furthermore, short circuit between the capacitors can readily be prevented, since film 8b to be the capacitor lower electrode is not left between the capacitors. This results in an improved yield of the semiconductor devices.

Third Embodiment

A manufacturing method of a semiconductor device according to the third embodiment of the present invention is described. The manufacturing method of the semiconductor device of the present embodiment is identical to the manufacturing method of the semiconductor device of the first embodiment up to the step of obtaining the structure shown in FIG. 9, or identical to the manufacturing method of the semiconductor device of the second embodiment up to the step of obtaining the structure shown in FIG. 17.

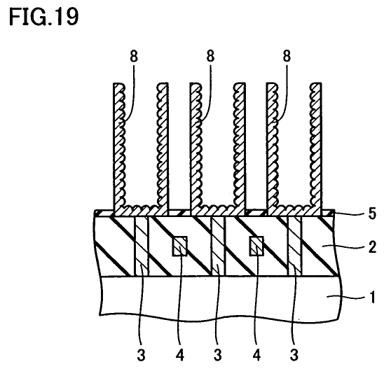

Thereafter, according to the manufacturing method of the semiconductor device of the present embodiment, in the structure shown in FIG. 9 or 17, a resist film is filled in the concave portion formed by capacitor lower electrode 8. Next, using the resist film as a mask, silicon nitride film 7 as the hard mask is removed by wet etching employing hot phosphoric acid. The structure shown in FIG. 18 is thus obtained. Thereafter, the resist film filled in the concave portion formed by capacitor lower electrode 8 is removed, followed by removal of interlayer insulating film 6 employing hydrofluoric acid. The structure shown in FIG. 19 is thus obtained.

According to the manufacturing method of the semiconductor device of the present embodiment, again, a semiconductor device increased in capacitance can be manufactured.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A manufacturing method of a semiconductor device, comprising the steps of:
forming an insulating film above a semiconductor substrate;
forming, on said insulating film, a hard mask harder to polish than said insulating film upon chemical mechanical polishing and having a greater selective ratio with respect to said insulating film than a resist film under a prescribed etching condition;
forming a hole penetrating said hard mask and said insulating film to extend in a vertical direction with respect to a main surface of said semiconductor substrate;
forming a capacitor lower electrode along a side surface of said hole;
forming a capacitor dielectric film along a surface of said capacitor lower electrode; and
forming a capacitor upper electrode to contact a surface of said capacitor dielectric film.

2. A manufacturing method of a semiconductor device, comprising the steps of:
forming a first insulating film above a semiconductor substrate;
forming, on said first insulating film, a second insulating film different in composition from said first insulating film;
forming, on said second insulating film, a hard mask same in composition with said first insulating film and harder to polish than said second insulating film upon chemical mechanical polishing;
forming, on said hard mask, an etching stopper film having a greater selective ratio than said hard mask under a prescribed etching condition;
forming, by etching with said etching stopper film used as a mask, a hole penetrating said etching stopper film, said hard mask, said second insulating film and said first insulating film to extend in a vertical direction with respect to a main surface of said semiconductor substrate;
forming a film to be a capacitor lower electrode on a side surface of said hole and an upper surface of said hard mask;
forming a buried film to bury said film to be the capacitor lower electrode;
forming the capacitor lower electrode by removing said buried film, said film to be the capacitor lower electrode and said etching stopper film by chemical mechanical polishing to expose said hard mask;
forming a capacitor dielectric film on a surface of said capacitor lower electrode; and
forming a capacitor upper electrode on a surface of said capacitor dielectric film.

3. A manufacturing method of a semiconductor device, comprising the steps of:
forming a first insulating film above a semiconductor substrate;
forming, on said first insulating film, a second insulating film different in composition from said first insulating film;
forming, on said second insulating film, a hard mask same in composition with said first insulating film and having a greater selective ratio with respect to said second insulating film than a resist film under a first prescribed etching condition;
forming, on said hard mask, an etching stopper film having a greater selective ratio than said hard mask under a second prescribed etching condition;
forming, by etching with said etching stopper film used as a mask, a hole penetrating said etching stopper film, said hard mask, said second insulating film and said first insulating film to extend in a vertical direction with respect to a main surface of said semiconductor substrate;
forming a film to be a capacitor lower electrode on a side surface of said hole and an upper surface of said hard mask;
forming a buried film to bury said film to be the capacitor lower electrode;
forming the capacitor lower electrode by removing said buried film, said film to be the capacitor lower electrode and said etching stopper film by chemical mechanical polishing to expose said hard mask;
forming a capacitor dielectric film on a surface of said capacitor lower electrode; and
forming a capacitor upper electrode on a surface of said capacitor dielectric film.
